(19) United States
(12) Patent Application Publication
(10) Pub. No.: US 2008/0199610 A1
(43) Pub. Date: Aug. 21, 2008

(54) Substrate processing apparatus, and substrate processing method

(75) Inventors: Yasuhiro Inokuchi, Toyama-shi (JP); Katsuhiko Yamamoto, Toyama-shi (JP); Atsushi Moriya, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., TOKYO (JP)

(21) Appl. No.: 12/071,259

(22) Filed: Feb. 19, 2008

(30) Foreign Application Priority Data
Feb. 21, 2007 (JP) 2007-041302

(51) Int. Cl. C23C 16/44

(52) U.S. Cl. 427/248.1; 118/729

(57) ABSTRACT

To move a substrate mounting part, on which substrates are stacked and mounted, when processing gas is supplied into a processing chamber and processing is applied to a surface of each substrate.

### BACKGROUND

1. Field of the Invention

The present invention relates to a substrate processing apparatus and a substrate processing method, and for example, relates to the substrate processing apparatus and the substrate processing method effective for being used in a heat treatment device (furnace) applying thermal treatment such as CVD (Chemical Vapor Deposition), diffusion, oxidization, and annealing to a semiconductor wafer having a semiconductor integrated circuit including a semiconductor element built-in, in a manufacturing method of a semiconductor integrated circuit device (called IC hereafter).

2. Related Art

In a film forming step in a manufacturing method of the IC, a batch type vertical hot wall pressure reducing CVD apparatus (called a CVD apparatus hereunder) is widely used. Generally, the CVD apparatus includes a process tube having a processing chamber formed for applying thermal treatment to the semiconductor wafer in a state of holding a plurality of wafers in a boat; a stand-by chamber formed just under the process tube, for waiting for loading and unloading the boat into/from the processing chamber; a boat elevator for elevating the boat to load and unload it into/from the processing chamber; a nozzle for supplying a processing gas to the processing chamber; and an exhaust tube for exhausting the processing chamber.

As such a kind of conventional CVD apparatus, there is given an example such as laying three nozzles having different heights to suppress a difference in film forming characteristic to be small, between each wafer disposed on an upper stage, disposed on an middle stage, and disposed on a lower stage (for example see patent document 1).
[Patent document 1] Japanese Patent Laid Open No. 2002-231635

However, in the CVD apparatus laying the three nozzles having different heights, there is a case such as generating the difference in film forming characteristic between a wafer disposed near a jetting port of each nozzle, and a wafer disposed at a position away from the jetting port.

In order to suppress the generation of the difference in film forming characteristic, the difference in film forming characteristic is considered to be suppressed to be small by finely adjusting a gas flow rate, etc. However, in some cases, a process window (processing condition range) may be small. Namely, when the difference in film forming characteristic is made to be small, between the wafer disposed near the jetting port and the wafer disposed at the position away from the jetting port, the difference is considered to be made small by adjusting the gas flow rate and a pressure However, when the characteristic difference is adjusted to be smallest, a film forming speed is decreased or other phenomenon may be generated in many cases. Therefore, it is necessary to find a compromising point of such cases and determine a process condition, and in some cases, a range of the process condition becomes significantly narrow. Namely, the process window becomes small in some cases. In addition, the wafer is arranged in the center of the process tube viewed from above, so that a distance between the wafer and an inner wall of the process tube is fixed. Therefore, generally, the film forming characteristic of the in-surfaces of the wafers has a circular shaped distribution.

An object of the present invention is to provide a substrate processing apparatus capable of reducing a difference in processing characteristic in a stacking direction, and a substrate processing method of the same. In addition, another object of the present invention is to provide the substrate processing apparatus capable of reducing a generation of the difference in processing characteristic of the in-surface of the substrate, and the substrate processing method of the same.

### SUMMARY OF THE INVENTION

A first aspect of the present invention provides a substrate processing apparatus, including;

a processing chamber that stores a substrate mounting part on which a plurality of substrates are stacked and mounted;

a vertical direction moving unit that moves the substrate mounting part in a stacking direction of the substrates;

a gas supply unit having a plurality of processing gas supply parts in the stacking direction of the substrates, being the gas supply unit for supplying a processing gas into the processing chamber, for applying processing to the surface of each substrate;

an exhaust unit that exhausts an atmosphere in the processing chamber;

a control unit that controls the vertical direction moving unit and the gas supply unit.

the control unit controlling the vertical direction moving unit, so that the substrate mounting part on which the substrate is mounted is moved in a stacking direction of the substrates, when the processing gas is supplied into the processing chamber from the processing gas supply part and the processing is applied to the surface of each substrate.

Another aspect of the present invention provides the substrate processing apparatus, including:

the processing chamber that stores a substrate mounting part on which a plurality of substrates are stacked and mounted;

a parallel direction moving unit that moves the substrate mounting part in a direction parallel to the surface of each substrate;

the gas supply unit having a plurality of processing gas supply parts in the stacking direction of the substrates, being the gas supply unit for supplying a processing gas into the processing chamber, for applying processing to the surface of each substrate;

an exhaust unit that exhausts the atmosphere in the processing chamber; and

the control unit that controls the parallel direction moving unit and the gas supply unit,

the control unit controlling the parallel direction moving unit, so that the substrate mounting part on which the substrate is mounted is moved in a parallel direction on the surface of each substrate, when the processing gas is supplied into the processing chamber from the processing gas supply parts and the processing is applied to the surface of each substrate.

Another aspect of the present invention provides the substrate processing apparatus, including:

the processing chamber that stores a substrate mounting part on which a plurality of substrates are stacked and mounted;

the vertical direction moving unit that moves the substrate mounting part in the stacking direction of the substrates;

the parallel direction moving unit that moves the substrate mounting part in the direction parallel to the surface of each substrate;

the gas supply unit having a plurality of processing gas supply parts in the stacking direction of the substrate, being the gas supply unit that supplies the processing gas into the processing chamber, for applying processing to the surface of the substrate;

the exhaust unit that exhausts the atmosphere in the processing chamber;

the control unit that controls the vertical direction moving unit, the parallel direction moving unit, and the gas supply unit,

the control unit controlling the vertical direction moving unit, so that the substrate mounting part on which the substrate is mounted is moved in the stacking direction of the substrate, when the processing gas is supplied into the processing chamber from the processing gas supply parts, and also controlling the parallel direction moving unit, so that the substrate mounting part on which the substrate is mounted is moved in the parallel direction on the surface of the substrate.

Another aspect of the present invention provides a substrate processing method, including:

substrate loading for loading the substrate mounting part, on which the plurality of substrates are mounted, into the processing chamber;

gas supplying for supplying gas for applying processing to the surface of the substrate into the processing chamber from at least two or more different positions in the stacking direction of the substrates;

a vertical moving for vertically moving the substrate mounting part in the stacking direction of the substrates in the processing chamber; and

a substrate unloading for unloading the substrate mounting part, on which the plurality of substrates are stacked and mounted, to the outside of the processing chamber.

Another aspect of the present invention provides the substrate processing method, including:

substrate loading for loading the substrate mounting part, on which the plurality of substrates are mounted, into the processing chamber;

gas supplying for supplying gas for applying processing to the surface of the substrate into the processing chamber from at least two or more different positions in the stacking direction of the substrates;

parallel moving for moving the substrate mounting part in the direction parallel to the surface of the substrate in the processing chamber; and

substrate unloading for unloading the substrata mounting part, on which the plurality of substrates are stacked and mounted, to the outside of the processing chamber.

According to the substrate processing apparatus and the substrate processing method of the present invention, the difference in processing characteristic in the stacking direction of the substrates can be reduced, or the generation of the difference in the processing characteristic of the in-surface of the substrate can be reduced.

### BRIEF DESCRIPTION OF THE DRAWINGS

FIG. 1 is a partially omitted perspective view illustrating a CVD apparatus according to an embodiment of the present invention.

FIG. 2 is a side sectional view illustrating a main essential part of this CVD apparatus.

FIG. 3 is a partially omitted side sectional view illustrating a state of elevating a boat during film formation.

FIG. 4 is a partially omitted side sectional view illustrating a state of lowering the boat during film formation.

FIG. 5 is a sectional block diagram of a processing furnace of a conventional CVD apparatus.

FIG. 6 is a sectional block diagram of the processing furnace of the CVD apparatus according to other embodiment of the present invention.

### BEST MODE FOR CARRYING OUT THE INVENTION

### An Embodiment of the Present Invention

An embodiment of the present invention will be explained hereunder, with reference to the drawings.

The substrate processing apparatus according to this embodiment is constituted, for example, as a CVD apparatus (batch type vertical hot wall pressure reducing CVD apparatus) 10.

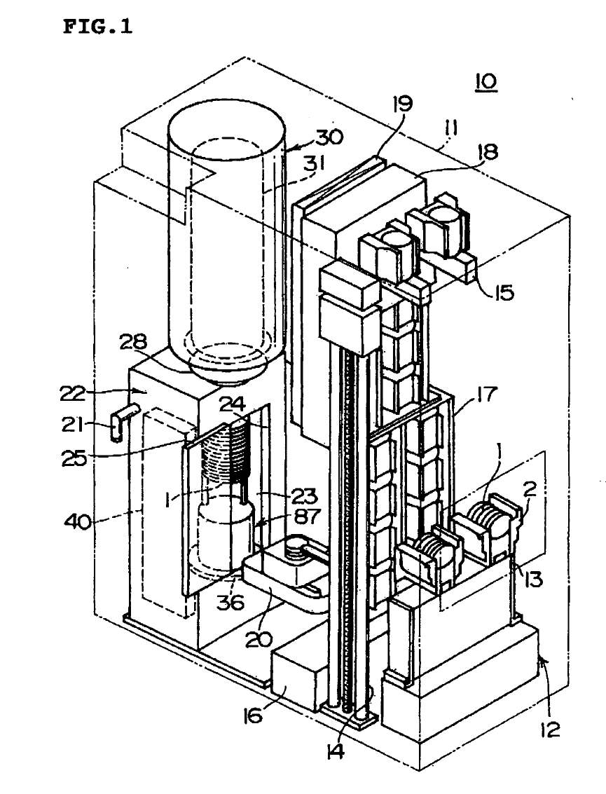

As shown in FIG. 1, the CVD apparatus 10 includes a casing 11, and a front surface of the casing 11 is equipped with a cassette receiving unit 12. The cassette receiving unit 12 has a cassette stage 13 allowing, for example, two sets of cassettes 2, being carriers for housing and carrying a wafer 1, being a substrate, to be mounted thereon. The cassette stage 13 is constituted, so that the cassette 2 is carried by an external carrying device (not shown), and the carried cassette 2 is mounted in a vertical posture (in a state that the wafer 1 housed in the cassette 2 is set in a vertical posture). Further, the cassette 13 is constituted, so that the cassette 2 is set in a horizontal posture by rotating the mounted cassette 2 by 90 degrees.

A cassette elevator 14 is installed behind the cassette stage 13, and the cassette elevator 14 is constituted, so that a cassette mounting device 15 is elevated. A cassette shelf 17 traversed by a slide stage 16 is set behind the cassette elevator 14. A buffer cassette shelf 18 is set in an upper part of the cassette shelf 17. A clean unit 19 for ventilating clean air into the casing 11 is set behind the buffer cassette shelf 18. Further, wafer transfer equipment 20 capable of transferring a plurality of wafers 1 collectively or one by one is set behind the cassette shelf 17 so as to be rotated and elevated.

A pressure-withstand casing 22 constructed so as to withstand a pressure is set in a lower part of a rear end portion of the casing 11. In the pressure-withstand casing 22, a stand-by chamber 23, in which a boat 87 is set in a stand-by mode, is formed inside as a substrate mounting part on which a plurality of wafers 1 are stacked and mounted. A structure of the boat 87 will be described later. An exhaust tube 21 for exhausting the inside of the stand-by chamber 23 to a pressure of under atmospheric pressure is connected to the pressure-withstand casing 22. A wafer loading/unloading port 24 is opened on a front surface wall of the pressure-withstand casing 22. The wafer loading/unloading port 24 is opened/closed by a load lock door 25.

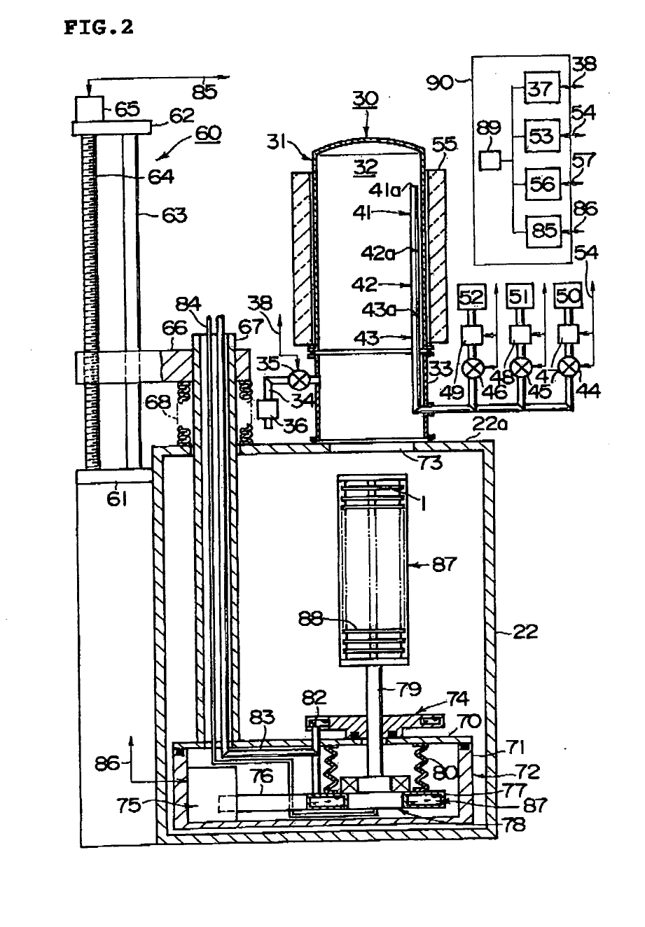

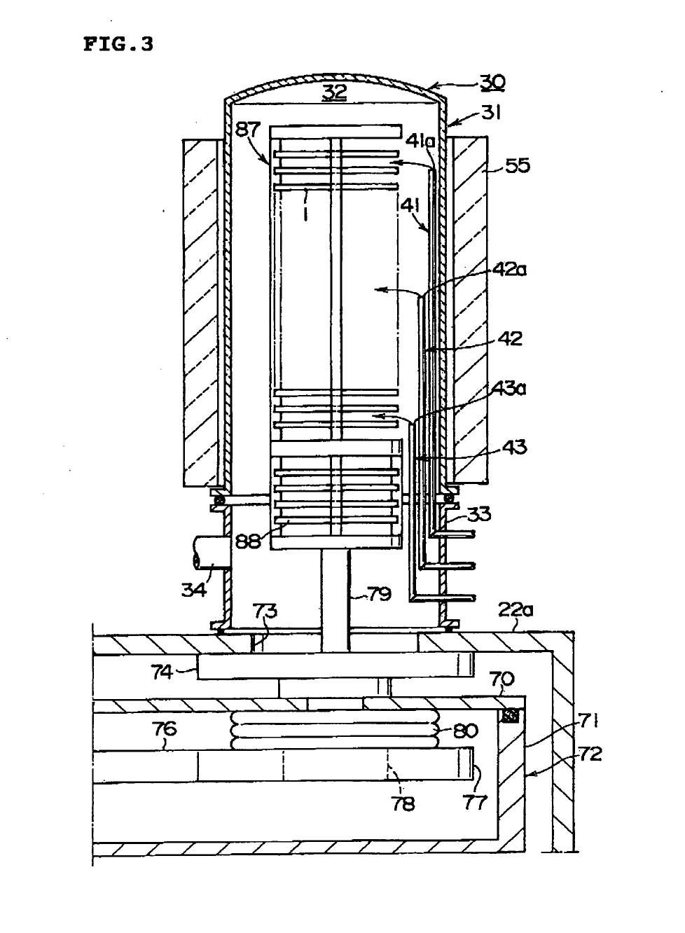

As shown in FIG. 2 and FIG. 3, a processing furnace 30 is installed above the pressure-withstand casing 22. The processing furnace 30 has a process tube 31. The process tube 31 is composed of quartz (SiO₂) or silicon carbide (SiC), formed in a cylindrical shape, with an upper end closed and lower end opened. A processing chamber 32 for housing the boat 87, in which a plurality of wafers 1 are stacked and mounted, is formed in a hollow tube inside of the process tube 31. Namely, the processing chamber 32 is constituted, so that the wafers 1, being the substrates, can be housed in a state of being arranged in multiple stages horizontally in a vertical direction by the boat 87.

A manifold 33 is disposed concentrically with the process tube 31 on the lower side of the process tube 31. The manifold 33 is formed by using, for example, stainless, with upper end and lower end opened in a cylindrical shape. The manifold 33 is provided so as to support the process tube 31. By supporting the manifold 33 by a support not shown, the process tube 31 is set in a state of being installed vertically. A reaction tube is formed by the process tube 31 and the manifold 33. Note that an O-ring as a sealing member is provided between the manifold 33 and the process tube 31.

An end of a gas exhaust tube 34 as the exhaust unit for exhausting the atmosphere in the processing chamber 32 is connected to the manifold 33. A vacuum exhaust device 36 such as a vacuum pump is connected to a lower stream side of the gas exhaust tube 34, via a pressure sensor (not shown) as a pressure detector and an APC valve 35 as a pressure adjusting unit. A pressure control unit 37 is electrically connected to the pressure sensor and the APC valve 35 by electric wiring 38. The pressure control unit 37 controls the pressure in the processing chamber 32 to be a desired pressure at a desired timing, by adjusting an opening degree of the APC valve 35 based on the pressure detected by the pressure sensor.

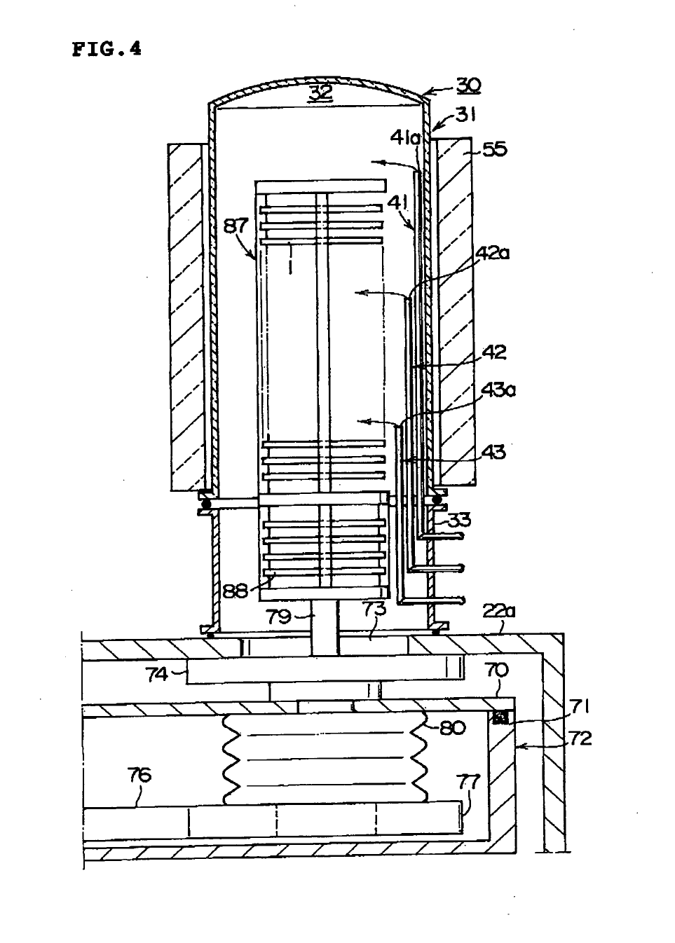

As shown in FIG. 2, FIG. 3, and FIG. 4, the processing chamber 32 has gas supply tubes 41, 42, 43 inside, as gas supply units for supplying into the processing chamber 32 the processing gas for applying processing to the surface of each wafer 1. Specifically, three gas supply tubes 41, 42, 43 having different heights of upper, middle, and lower stages are laid in the processing chamber 32. A nozzle for supplying the processing gas into the processing chamber 32 is formed on the lower stream side end portion of the gas supply tubes 41, 42, 43. Namely, the gas supply tubes 41, 42, 43 have jetting ports 41a, 42a, 43a as a plurality of processing gas supply parts in the stacking direction of the wafers 1. The jetting ports 41a, 42a, 43a, being the gas supply parts of the three gas supply tubes 41, 42, 43 are respectively disposed on the upper, middle, and lower stages in the processing chamber 32. The manifold 33 is penetrated and pulled out to the outside on the upper stream end portion of the three gas supply tubes 41, 42, 43. Gas supply sources 50, 51, 52 are respectively connected to the upper stream side end portion of the three gas supply tubes 41, 42, 43, via valves 44, 45, 46, and MFCs 47, 48, 49 as a gas flow control device. A gas flow controller 53 is electrically connected to the MFCs 47, 48, 49 and the valves 44, 45, 46 by electric wiring 54. The gas flow controller 53 controls the MFC 47, 48, 49 and the valves 44, 45, 46 at a desired timing, so that a flow rate of the gas supplied into the processing chamber 32 reaches a desired flow rate. Note that in FIG. 3 and FIG. 4, the three gas supply tubes 41, 42, 43 are shown so as to be deviated in a vertical direction and in a diameter direction for convenience. However, actually the three gas supply tubes 41, 42, 43 are disposed so as to be deviated in the vertical direction and a peripheral direction (so as to be deviated in the peripheral direction of an inner wall of the processing chamber 32). In addition, the jetting ports 41a, 42a, 43a according to this embodiment are faced upward. However, they may be faced horizontally. Further, the jetting ports 41a, 42a, 43a are disposed only on the lower stream side end portion of the gas supply tubes 41, 42, 43. However, the jetting ports may be formed not only on the lower stream side end portion but also on the way from the upper stream side to the lower stream side.

As shown in FIG. 2 and FIG. 3, the processing furnace 30 has a heater 55 as a heating section. The heater 55 is constructed in a cylinder shape by a heater element and a heat insulating member disposed around the heater element, concentrically arranged at the outside of the process tube 31. The heater 55 is vertically installed on the pressure-withstand casing 22 by being supported by a support (not shown). A temperature sensor (not shown) as a temperature detector for detecting a temperature in the processing chamber 32 is disposed near the heater 55. A temperature controller 56 is electrically connected to the heater 55 and the temperature sensor by electric wiring 57. The temperature controller 56 controls the temperature in the processing chamber 32 to have a desired temperature distribution by adjusting a power supply condition to the heater 55 at a desired timing based on temperature information detected by the temperature sensor. Note that the heater 55 is disposed to be vertically longer than a support area of the wafers 1 in the boat 87 so as to cover a vertically movable area of the boat 87 moved by a vertical direction moving unit as will be described later.

As shown in FIG. 2, a boat elevator 60 is disposed in the pressure-withstand casing 22. The boat elevator 60 includes a lower side fitting plate 61 and an upper side fitting plate 62. A guide shaft 63 and a screw shaft 64 are vertically laid between the lower side fitting plate 61 and the upper side fitting plate 62. The screw shaft 64 is rotated in a regular direction or in a reverse direction by an elevating motor 65 disposed on the upper side fitting plate 62. An elevation table 66 is engaged with the guide shaft 63 and the screw shaft 64, so that the elevation table 66 is guided and elevated by the guide shaft 63 in association with the rotation of the screw shaft 64.

A hollow elevating shaft 67 is vertically disposed on the elevation table 66. The elevating shaft 67 is elevated together with the elevating table 66. A connection part between the elevating table 66 and the elevating shaft 67 is air-tightly formed. The elevating shaft 67 penetrates a top plate 22a of the pressure-withstand casing 22. A through hole of the top plate 22a where the elevating shaft 67 penetrates has a sufficient space to avoid touching on the elevating shaft 67. A bellows 68 as a hollow expanding body having expandability is disposed so as to cover the periphery of the elevating shaft 67 to air-tightly maintain an inside of the pressure-withstand casing 22. The bellows 68 has a sufficient expandability capable of responding to an elevating amount of the elevating table 66. An inner diameter of the bellows 68 is larger than an external shape of the elevating shaft 67 and is formed to avoid touching on the elevating shaft 67 by expansion of the bellows 68.

An elevating plate 70 is horizontally disposed and fixed to a lower end of the elevating shaft 67. A drive section cover 71 is air-tightly fitted to a lower surface of the elevating plate 70 via a sealing member such as an O-ring. A drive section storing case 72 is constituted by the elevating plate 70 and the drive section cover 71. With this structure, the inside of the drive section storing case 72 is shut off from the atmosphere in the pressure-withstand casing 22.

A seal cap 74 as a throat lid member for air-tightly closing a throat 73 opened in the top plate 22a of the pressure-withstand casing 22 is disposed on the elevating plate 70. The seal cap 74 is constituted of metal such as stainless and is formed in a disc shape. The O-ring is disposed on the upper surface of the seal cap 74, as a sealing member in contact with an opening edge side of the throat 73. Usually, the throat 73 is closed by a shutter 28 (see FIG. 1).

A linear actuator 75 is set in the drive storing case 72. An arm 76 is vertically elevated by the linear actuator 75. An elevation table 77 is horizontally supported by the arm 76. A vertical direction moving unit for moving the boat 87 in the stacking direction of the wafers 1 is constituted by the linear actuator 75, the arm 76, and the elevation table 77.

A moving frequency (moving speed) of the boat 87 by the vertical direction moving unit is preferably set as a frequency (speed) of, for example, one reciprocation of the boat 87 or for example, half reciprocation of the boat 87 in a period of one execution of the gas supplying step as will be described later (in a period after the processing gas is started to be supplied into the processing chamber 32 until the end of the supply). By moving the boat 87 with such a frequency (speed), processing conditions such as a gas supply flow rate can be made uniform between the wafers 1 arranged near the jetting ports 41a, 42a, 43a, and the wafers 1 disposed at a position away from the jetting ports 41a, 42a, 43a, thus making it possible to inhibit or suppress the generation of the difference in film forming characteristics. Note that it is preferable to individually adjust the moving frequency (moving speed) of the boat 87 by the vertical direction moving unit, by a content or processing performed in the processing chamber 32, the kind of the processing gas supplied into the processing chamber 32, the number of wafers 1 to be processed, a size of the processing chamber 32, and a distance between each jetting ports.

A moving width (moving distance) of the boat 87 by the vertical direction moving unit is preferably set to be a half of the distance between the jetting ports 41a, 42a, 43a. By thus limiting an area allowing the boat 87 to move, the processing conditions such as the gas supply flow rate can be made uniform, between the wafers 1 arranged near the jetting ports 41a, 42a, 43a, and the wafers 1 arranged at apposition away from the jetting ports 41a, 42a, 43a, thus making it possible to inhibit or suppress the difference in film forming characteristic.

An upper limit position (height position) of the boat 87 moved by the vertical direction moving unit is preferably set to be not more than the height position of the jetting port 41a, being an uppermost part of the processing gas supply parts. Namely, when the boat 87 is moved by the vertical direction moving unit, the height position of the wafer 1 of the uppermost part of the processed wafers 1 supported by the boat 87 is preferably set to be always same as the height position of the jetting port 41a or less. By thus limiting the area that allows the boat 87 to move, the processing conditions such as the gas supply flow rate can be made further uniform, between respective wafers supported in the upper, middle, lower parts in the boat 87, thus making it possible to inhibit or suppress the generation of the difference in film forming characteristic. Namely, it is possible to suppress such a case as making the gas supply flow rate to the wafer 1 supported by the upper part (upper stream part of the gas) in the boat 87 smaller than the gas supply flow rate to the wafer 1 supported by the middle and lower parts (middle stream and lower stream parts of the gas) in the boat 87.

A moving direction of the boat 87 at a time point of starting the gas supply step as will be described later (supply start time point of the processing gas into the processing chamber 32) is preferably set to be a lower stream direction of the processing gas. Namely, preferably the position of the boat 87 at the time point of starting the forming step of a CVD film (initial position of the boat 87) is set as the upper limit position of a movable area of the boat 87, and the boat 87 is lowered in accordance with a progression of the forming step of the CVD film. By thus limiting the moving direction of the boat 87, the processing conditions such as the gas supply flow rate can be made further uniform between the respective wafers 1 supported in the upper, middle, and lower parts in the boat 87, thus making it possible to inhibit or suppress the generation of the difference in film forming characteristic. Namely, it is possible to suppress such a case as making the gas supply amount to the wafer 1 supported by the upper part (upper stream part of the gas) in the boat 87 smaller than the gas supply flow rate to the wafer 1 supported by the middle and lower parts (middle stream and lower stream parts) in the boat 87.

In addition, the moving distance of the boat 87 moved by the vertical direction moving unit is preferably set to be the distance in which the wafer 1 supported by the boat 87 is always heated by the heater 55. Namely, the moving distance of the boat 87 is preferably limited, so that the height position of the wafer 1 of the uppermost part of the processed wafer 1 supported by the boat 87 and the height position of the wafer 1 of the lowermost part are respectively incorporated within a heated area by the heater 55 (within an area in which the heater 55 is provided). By limiting the area that allows the boat 87 to move, a temperature condition can be made uniform between the respective wafers 1 supported in the upper, middle, and lower parts in the boat 87, thus making it possible to inhibit or suppress the generation of the difference in film forming characteristic.

The elevation table 77 is set, with a rotary shaft 79 of a rotating mechanism 78 faced upward. A bellows 80 for air-tightly maintaining a circumference of the rotary shaft is set around the rotary shaft 79 in the drive storing case 72. A cooling mechanism 81 is set in the periphery of the rotating mechanism 78. A cooling flow path 82 is formed in the cooling mechanism 81 and the seal cap 74. A cooling water piping 83 for supplying cooling water is connected to the cooing flow path 82. The cooling water piping 83 passes through a hollow part of the elevating shaft 67 from an upper end of the elevating shaft 67. In addition, a power supply cable 84 is guided through the hollow part of the elevating shaft 67 from the upper end of the elevating shaft 67, and is connected to the rotating mechanism 78.

A drive controller 85 is electrically connected to the linear actuator 75, the rotating mechanism 78, and the elevating motor 65 by electric wiring 86. The drive controller 85 controls the linear actuator 75, the rotating mechanism 78, and the elevating motor 65, so as to perform a desired operation at a desired timing. By rotating the screw shaft 64 when driven by the elevating motor 65, the drive section storing case 72 is elevated via the elevation table 66 and the elevating shaft 67. By elevating the drive section storing case 72, the seal cap 74 which is air-tightly disposed in the elevating plate 70 closes the throat 73, being an opening part of the processing furnace 30, so that a state capable of performing wafer processing is obtained. By lowering of the drive section storing case 72, the boat 84 is also lowered together with the seal cap 74, thus making it possible to unload the wafer 1 to the outside.

The rotary shaft 79 of the rotating mechanism 78 penetrates the seal cap 74 and is connected to the boat 87. By rotating the boat 87, the wafer 1 is also rotated. The boat 87 as a substrate mounting part, is composed of a heat-withstand material such as quartz or silicon carbide, and is constituted so that a plurality of wafers 1 are held in multiple stages, in a state of being arranged in a horizontal posture, with centers thereof mutually aligned. Note that a plurality of heat insulating plates 88 as heat insulating members having a disc shape composed of a heat-withstand material such as quartz and silicon carbide are horizontally arranged in a lower part of the boat 87 in multiple stages, so that heat from the heater 55 is hardly transmitted to the manifold 33 side.

In addition, the pressure controller 37, the gas flow rate controller 53, the temperature controller 56, and the drive controller 85 constitute the operation part and the input/output part, and are electrically connected to the main controller 89 that controls an entire body of the CVD apparatus 10. These pressure controller 37, gas flow rate controller 53, temperature controller 56, drive controller 85, and main controller 89 are constituted as a controller 90.

An action of the CVD apparatus according to the aforementioned structure, namely, a CVD thin film forming step as a substrate processing step will be explained hereunder.

The CVD film forming step according to this embodiment is executed as one step of a manufacturing step of the semiconductor device such as an IC. An operation of each part constituting the CVD apparatus 10 is controlled by the controller 90.

The CVD thin film forming step according to this embodiment includes loading of a substrate for loading the boat 87, on which a plurality of wafers 1 are stacked and mounted, into the processing chamber 32; supplying gas for supplying the gas for applying processing to the surface of each wafer 1 into the processing chamber 32 from at least two different positions in a stacking direction of the wafer 1; vertically moving the boat 87 in the stacking direction of the wafer 1 in the processing chamber 32; and unloading the substrate for unloading the boat 87, on which a plurality of wafers 1 are stacked and mounted, outside of the processing chamber 32.

### (Substrate Loading Step)

A cassette 2, in which a plurality of wafers 1 are stored, is supplied on a cassette stage 13 of a cassette receiving unit 12 by an external carrying device. The cassette 2 supplied on the cassette stage 13 is rotated at 90 degrees and set in a horizontal posture. The cassette 2 thus set in the horizontal posture is carried and transferred onto a cassette shelf 17 or a buffer cassette shelf 18 by a cassette transfer device 15.

The wafer 1 to be processed stored in the cassette 2 is loaded into the stand-by chamber 23 through the wafer loading/unloading port 24 of the pressure-withstand casing 22, and is charged into the boat 87. At this time, as shown in FIG. 1, by shutting the throat 73 by the shutter 28, a high temperature atmosphere in the processing chamber 31 is prevented from flowing into the stand-by chamber 23. Therefore, the wafer 1 in the middle of being charged into the boat 87 and the wafer 1 already charged into the boat 87 are prevented from being exposed to the high temperature atmosphere, and the generation of an adverse effect such as natural oxidization caused by exposing the wafer 1 to the high temperature atmosphere can be prevented.

When the designated number of wafers 1 are charged into the boat 87, the wafer loading/unloading port 24 is closed by a load lock door 25, and the throat 73 is opened by the shutter 28.

Subsequently, as shown in FIG. 3, the boat 87 holding a plurality of wafers 1 is loaded into the processing chamber 32, by an elevating operation of the elevation table 66 and the elevating shaft 67 operated by the elevating motor 65. In this state, the throat 73 is set in a closed state by the seal cap 74.

### (Pressure Reducing Step and Temperature Increasing Step)

The inside of the processing chamber 32 is evacuated by an evacuating device 36, so as to reach a desired pressure (vacuum state). At this time, the pressure in the processing chamber 32 is measured by a pressure sensor, and based on the measured pressure, a pressure adjuster 35 is feedback-controlled. In addition, the inside of the processing chamber 32 is heated by the heater 55 so as to reach a desired temperature (temperature increasing step). At this time, a power supply condition to the heater 55 is feedback-controlled based on temperature information detected by the temperature sensor, so that the inside of the processing chamber 32 has a desired temperature distribution.

### (Vertical Moving Step)

Subsequently, as shown in FIG. 3 and FIG. 4, by elevating the boat 87 by the vertical direction moving unit (linear actuator 75. etc), the wafer 1 is elevated (vertical moving step). Note that the vertical moving step may be started simultaneously with the start of the gas supplying step as will be described later or may be started prior to the start of the gas supplying step. In addition, the vertical moving step is executed by at least the time of completing the gas supplying step as will be described later (namely, by the time of stopping the supply of the processing gas into the processing chamber 32). At this time, the boat 87 may be rotated by the rotating mechanism 78 to rotate the wafer 1.

### (Gas Supplying Step)

The processing gas is supplied from processing gas supply sources 50, 51, 52, along with the execution of the vertical moving step. Valves 44, 45, 46 are opened, while adjusting an opening degree of MFCs 47, 48, 49, so that the flow rate of the processing gas becomes a desired flow rate. The processing gas is flown through gas supply tubes 41, 42, 43, and is introduced into the processing chamber 32 from an upper part of the processing chamber 32. The introduced processing gas passes through the processing chamber and is exhausted from a gas exhaust tube 34. The processing gas is brought into contact with the wafer 1 while passing through the processing chamber 32, and the CVD film is formed on the surface of the wafer 1.

Incidentally, the jetting ports 41a, 42a, 43a of the three gas supply tubes 41, 42, 43 are respectively disposed in the upper, middle, and lower stages in the processing chamber. Therefore, supply parts of the processing gas are dispersed in the upper, middle, and lower stages in the processing chamber 32. Accordingly, the difference in film forming characteristic (difference in film thickness) of the CVD film between the respective wafers in an entire length of the boat 87 is suppressed to be small, compared to a case of supplying the processing gas into the processing chamber 32 from an uppermost one place. However, in some cases, there is a case that the difference in film forming characteristic occurs, between the wafers 1 respectively disposed near each of the jetting ports 41a, 42a, 43a of the three gas supply tubes 41, 42, 43, and the wafers 1 disposed at the position away from each of the jetting ports 41a, 42a, 43a.

In this embodiment, as shown in FIG. 3 and FIG. 4, by elevating the boat 87 by the linear actuator 75, the wafer 1 is elevated. Therefore, a relative position between each of the jetting ports 41a, 42a, 43a of the three gas supply tubes 41, 42, 43 and the wafers 1 is changed, and the generation of the difference in film forming characteristic is inhibited or suppressed, between the wafers 1 respectively disposed near each of the jetting ports 41a, 42, 43a and the wafers 1 disposed at the position away from each of the jetting ports 41a, 42a, 43a. Simultaneously, the wafer 1 is rotated by rotating the boat 87 by the rotating mechanism 78, and therefore the difference in film forming characteristic (uniformity of the film thickness distribution) of the in-surfaces of the wafers 1 is suppressed.

When a previously set time is elapsed, inert gas is supplied from an inert gas supply source not shown, and the inside of the processing chamber 32 is replaced with the inert gas and the pressure in the processing chamber 32 is returned to a normal pressure.

### (Substrate Unloading Step)

Thereafter, the boat 87 is moved to the same position as the position for loading the boat 87 into the processing chamber 32, and the boat 87 is unloaded from the processing chamber 32. Namely, the seal cap 74 is lowered by the elevating motor 65, the lower end of the manifold 33 is opened, and the already processed wafer 1 is unloaded to the outside of the process tube 31 from the lower end of the manifold 33 in a state of being held by the boat 84 (boat unloading). Thereafter, the already processed wafer 1 is taken out from the boat 84 and is returned to the cassette 2 (wafer discharge).

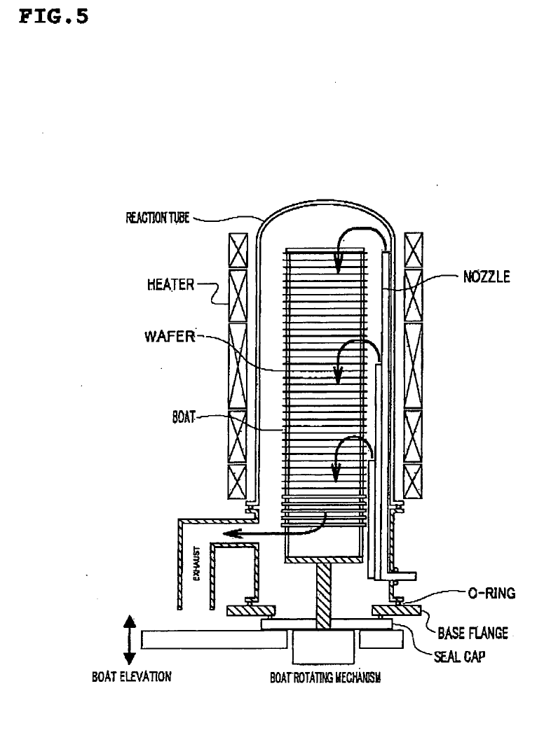

According to the aforementioned embodiment, the following one or more advantages can be obtained.
1) By constituting the boat in the processing chamber 32 so as to be elevated by the vertical direction moving unit (linear actuator 75, etc.) and elevating the vertical direction moving unit (linear actuator 75, etc.) by the boat 87 during film formation, the relative position between the jetting ports 41a, 42a, 43a of the gas supply tubes 41, 42, 43 and the wafers 1 can be changed. Therefore, the generation of the difference in film forming characteristic can be inhibited or suppressed, between the wafers 1 disposed near each of the jetting ports 41a, 42a, 43a, and the wafers 1 disposed at the position away from the jetting ports 41a, 42a, 43a. FIG. 5 shows a sectional block diagram of the processing furnace of a conventional CVD apparatus, for reference. The conventional CVD apparatus has three nozzles having different heights, and from such nozzles the processing gas is supplied into a reaction tube. Then, the height position of the boat supporting the wafer is fixed during film formation (while the processing gas is supplied). In this case, a supply amount of the processing gas is sometimes non-uniform between the wafers disposed near the jetting port of each nozzle and the wafers disposed at the position away from the jetting port, thus causing the difference in film forming characteristic to occur. Meanwhile, according to this embodiment, the relative position between the jetting ports 41a, 42a, 43a of the gas supply tubes 41, 42, 43, and the wafers 1 can be changed, thereby making it possible to solve the above-described problem. Note that as is shown in this embodiment, when the jetting ports 41a, 42a, 43a of the three gas supply tubes 41, 42, 43 are respectively opened upward (when the processing gas is jetted upward), it is particularly effective to provide the vertical direction moving unit for moving the boat 87 in the stacking direction of the wafer 1, to reduce the difference in film forming characteristic in the stacking direction of the wafers 1.
2) By suppressing the difference in film forming characteristic between the respective wafers 1, performance, quality and reliability of the CVD apparatus 10 can be improved and the quality and the reliability of the IC acquired from this wafer 1 can be made uniform.
3) By elevating and rotating the boat 87 in the processing chamber 32, both of the difference in film forming characteristic between the respective wafers 1 in the boat 87 and the difference in film forming characteristic of the in-surfaces of the wafers 1 can be suppressed.
4) The moving frequency (moving speed) of the boat 87 moved by the vertical direction moving unit can be set as the frequency (speed) of, for example, one reciprocation of the boat 87 or for example, half reciprocation of the boat 87 in a period of one execution of the forming step of the CVD film. By moving the boat 87 at such a frequency (speed), the processing conditions such as gas supply flow rate can be made uniform, between the wafers 1 disposed near the jetting ports 41a, 42a, 43a, and the wafers 1 disposed at the position away from the jetting ports 41a, 42a, 43a, thus making it possible to inhibit or suppress the generation of the difference in film forming characteristic.
5) A moving width (moving distance) of the boat 87 by the vertical direction moving unit can be set as approximately half of the distance between the jetting ports 41a, 42a, 43a. By thus limiting the area that allows the boat 87 to move, the processing conditions such as gas supply flow rate can be made uniform, between the wafers disposed near the jetting ports 41a, 42a, 43a, and the wafers 1 disposed at the position away from the jetting ports 41a, 42a, 43a, thus making it possible to inhibit or suppress the generation of the difference in film forming characteristic.
6) The upper limit position (upper limit height position) of the boat 87 moved by the vertical direction moving unit can be set as not more than the height position of the jetting port 41a, being the uppermost part of a plurality of processing gas supply parts. By thus limiting the area that allows the boat 87 to move, the processing conditions such as gas supply flow rate can be made uniform, between the respective wafers 1 supported in the upper, middle, and lower parts in the boat 87, thus making it possible to inhibit or suppress the generation of the difference in film forming characteristic.
7) The moving direction of the boat 87 at the time point of starting the forming step of the CVD film (start time point of supplying the processing gas into the processing chamber 32) can be set as the lower stream direction of the processing gas. By thus limiting the moving direction of the boat 87, the processing conditions such as gas supply flow rate can be made uniform, between the respective wafers 1 supported in the upper, middle, and lower parts in the boat 87, thus making it possible to inhibit or suppress the generation of the difference in film forming characteristic.
8) The moving distance of the boat 87 moved by the vertical direction moving unit can be limited to the distance where the wafer supported by the boat 87 is always heated by the heater 55. By thus limiting the area that allows the boat 87 to move, the temperature condition can be made uniform between the respective wafers 1 supported in the upper, middle, and lower parts in the boat 87, thus making it possible to inhibit or suppress the generation of the difference in film forming characteristic.

### Other Embodiment of the Present Invention

The CVD apparatus according to this embodiment is different from the aforementioned embodiment in the point that it has a parallel direction moving unit for moving the boat 87 in a direction parallel to the surface of the wafer 1. In other point, it is the same as the aforementioned embodiment. The parallel direction moving unit is constituted of the linear actuator 75, the arm 76, and the elevation table 77. The linear actuator according to this embodiment is constituted so that the arm 76 is moved in the direction parallel to the surface of the wafer 1.

Then, by the CVD apparatus 10 according to this embodiment, the parallel moving step for moving the boat 87 in the direction parallel to the surface of the wafer 1 in the processing chamber 32 is executed.

In the parallel moving step, first, the boat 87 loaded into the processing chamber 32 is moved and fixed by the parallel direction moving unit before the gas supply step is executed (before the supply of the processing gas into the processing chamber 32 is started). When the jetting ports 41a, 42a, 43a and the gas exhaust tube 34 are not at symmetrical positions on both sides of a center axis of the processing chamber 32 (namely, when centers of the jetting ports 41a, 42a, 43a, the gas exhaust tube 34, and the processing chamber 32 are not on the same straight line), flow of the processing gas in the processing chamber 32 is not a symmetrical flow to the center axis of the processing chamber 32, but for example is an asymmetrical flow in which the supply amount of the processing gas is deviated toward the gas exhaust tube 34. In this case, preferably the parallel direction moving unit moves the boat 87 to a prescribed position which is asymmetrical to the center axis of the processing chamber and fixes the boat 87 to this position. For example, preferably the parallel direction moving unit moves the boat 87 to a prescribe position near the inner wall side of the processing chamber 32 in a direction provided with the exhaust tube 34 (position near the inner wall of the processing chamber 32 having an opening part of the gas exhaust tube 34 in the processing chamber 32) and fixes the boat 87 to this position.

Then, while the forming step of the CVD film is executed once (from the start of supply of the processing gas into the processing chamber 32 to the end of the supply), the parallel direction moving unit fixes the boat 87 to the aforementioned prescribed position or makes the boat 87 perform reciprocal movement in one direction parallel to the surface of the wafer 1.

Note that preferably the distance between an outer edge portion of the boat 87 (outer edge portion of the wafer 1 supported by the boat 87) moved by the parallel direction moving unit and the inner wall of the processing chamber 32 is not less than the distance between stacked wafers 1 (stacking pitch). Specifically, preferably the distance between the outer edge portion of the boat 87 and the inner wall of the processing chamber 32 is nearly equal to the distance (stacking pitch) between the stacked wafers 1. Note that in order to secure a clearance between a support of the boat 87 and the inner wall of the processing chamber 32, the distance between the outer edge portion of the boat 87 and the inner wall of the processing chamber may be set at about 10 nm. Note that the distance between the outer edge portion of the boat 87 and the inner wall of the processing chamber 32 is preferably individually adjusted, depending on a content of the processing performed in the processing chamber 32, the kind of the processing gas supplied into the processing chamber 32, the number of wafers 1 to be processed, and a size of the processing chamber 32.

According to this embodiment, the following one or more advantages can be obtained.
1) Depending on the distance between the outer edge portion of the boat 87 (outer edge portion of the wafer 1 supported by the boat 87) and the inner wall of the processing chamber 32, the flow rate of the processing gas supplied to the outer edge portion of the wafer 1 is sometimes more increased than the flow rate of the processing gas supplied to a center portion of this wafer 1. Namely, a distribution of the supply amount of the processing gas of the in-surface of the wafer 1 is formed in a circular shape, thus providing a non-uniform supply amount of the processing gas. According to this embodiment, by moving the boat in parallel, thereby adjusting the distance between the outer edge portion of the boat 87 (outer edge portion of the wafer 1 supported by the boat 87) and the inner wall of the processing chamber 32, an amount of the processing gas supplied onto the wafer 1 can be adjusted. For example, the distance between the outer edge portion of the boat 87 (outer edge portion of the wafer 1 supported by the boat 87) and the inner wall of the processing chamber 32 can be set to be not less than the distance between stacked wafers 1 (stacking pitch). Specifically, the distance between the boat 87 and the inner wall of the processing chamber 32 can be set to be nearly equal to the distance between stacked wafers 1 (stacking pitch). Thus, the flow rate of the processing gas supplied to the in-surface of the wafer 1 can be made uniform and the generation of the difference in film forming characteristic of in-surfaces of the wafers 1 can be inhibited or suppressed.
2) When the jetting ports 41a, 42a, 43a and the gas exhaust tube 34 are not at a symmetrical position on both sides of the center of the processing chamber 32 (when the centers of the jetting ports 41a, 42a, 43a, the gas exhaust tube 34, and the processing chamber 32 are not on the same straight line), the flow of the processing gas in the processing chamber 32 is not the symmetrical flow to the center axis of the processing chamber 32 but is the asymmetrical flow in which the supply amount of the processing gas is deviated toward the gas exhaust tube 34. In this case, supply of the processing gas into the wafer 1 is made non-uniform. According to this embodiment, the parallel direction moving unit can move the boat 87 to a prescribed position which is symmetrical to the center axis of the processing chamber 32 and fixes the boat 87 to this position. For example, the parallel direction moving unit moves the boat 87 to the prescribed position near the inner wall side of the processing chamber 32 in a direction provided with the gas exhaust tube 34 and fixes the boat 87 to this position. Thus, the flow rate of the processing gas supplied to the in-surfaces of the wafers 1 can be further made uniform and the generation of the difference in film forming characteristic of the in-surfaces of the wafers 1 can be inhibited or suppressed.
3) In some cases, inclination occurs to the boat 87 loaded into the processing chamber 32 and the distance between the outer edge portion of the boat 87 (outer edge portion of the wafer 1 supported by the boat 87) and the inner wall of the processing chamber 32 is differentiated by mm orders according to the height position in the processing chamber 32. Then, the amount of the processing gas supplied onto the wafers 1 becomes different according to the height position in the processing chamber 32, thus allowing the difference in film forming characteristic to occur between the respective wafers 1. According to this embodiment, by moving the boat 87 in parallel, thereby adjusting the distance between the outer edge portion of the boat 87 (outer edge portion of the wafer 1 supported by the boat 87) and the inner wall of the processing chamber 32, the flow rate of the processing gas supplied onto the wafers 1 can be made uniform in a height direction in the processing chamber 32, thus making it possible to inhibit or suppress the generation of the film forming characteristic between the respective wafers 1.

### Further Other Embodiment of the Present Invention

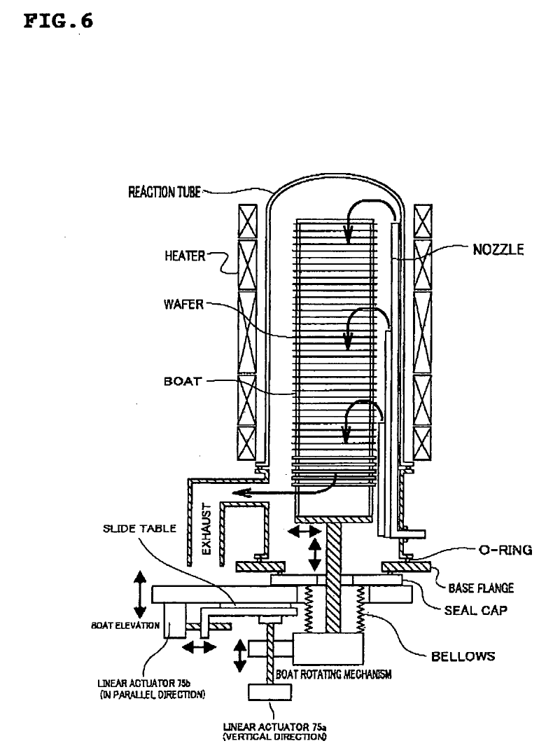

The CVD apparatus according to the aforementioned embodiment has either one of the vertical direction moving unit for moving the boat 87 in the stacking direction of the wafer 1 or the parallel direction moving unit for moving the boat 87 in the direction parallel to the surface of the wafer 1. However, the present invention is not limited to the aforementioned embodiment. Namely, the CVD apparatus according to the present invention may have both of the vertical direction moving unit and the parallel direction moving unit. Then, in this case, the linear actuator 75 may vertically elevate the arm 76 and move the arm 76 in parallel direction to the surface of the wafer 1. Alternately, as shown in FIG. 6, the linear actuators 75a and 75b may be provided individually in the vertical direction and the parallel direction.

Note that the present invention is not limited to the above-described embodiment, and can be variously modified in a range not departing from the gist of the present invention.

For example, a gas supply part having a plurality of processing gas supply parts in the stacking direction of the substrate is not limited to the structure in which a plurality of gas supply tubes having different jetting ports are provided, and may be constituted of one gas supply tube, with a plurality of jetting ports arranged in the height direction.

A moving part for moving the boat in the stacking direction of the wafer is not limited to the structure of including the linear actuator installed in the drive section storing case, and may also include a boat elevator.

In the above-described embodiment, the CVD apparatus has been explained. However, the present invention is not limited thereto, and can be applied to the substrate processing apparatus generally.

### <Preferred Aspect of the Present Invention>

Further, preferred aspects of the present invention will be additionally described.

One of the aspects of the present invention provides a substrate processing apparatus, including:

a processing chamber that stores a substrate mounting part on which a plurality of substrates are stacked and mounted;

a vertical direction moving unit that moves the substrate mounting part in a stacking direction of the substrates;

a gas supply unit having a plurality of processing gas supply parts in the stacking direction of the substrates, being the gas supply unit that supplies into the processing chamber processing gas for applying processing to a surface of each substrate;

an exhaust unit that exhausts an atmosphere in the processing chamber;

a controller that controls the vertical direction moving unit and the gas supply unit,

the controller controlling the vertical direction moving unit so that the substrate mounting part, on which the substrates are mounted, is moved in the stacking direction of the substrates, when the processing gas is supplied into the processing chamber from the processing gas supply parts and applying processing to the surface of the substrate.

Another aspect of the present invention provides the substrate processing apparatus, including:

the processing chamber that stores the substrate mounting part on which a plurality of substrates are stacked and mounted;

a parallel direction moving unit that moves the substrate mounting part in a direction parallel to the surface of each substrate;

the gas supply unit having a plurality of processing gas supply parts in the stacking direction of the substrates, being the gas supply unit that supplies the processing gas into the processing chamber for applying processing to the surface of the substrate;

the exhaust unit that exhausts the atmosphere in the processing chamber; and

a controller that controls the parallel direction moving unit and the gas supply unit,

the controller controlling the parallel direction moving unit so that the substrate mounting part, on which the substrates are mounted, is moved in a direction parallel to the surface of the substrate, when the processing gas is supplied into the processing chamber from the processing gas supply parts and processing is applied to the surface of the substrate.

Another aspect of the present invention provides the substrate processing apparatus, including:

the processing chamber that stores the substrate mounting part on which a plurality of substrates are stacked and mounted;

the vertical direction moving unit that moves the substrate mounting part in a stacking direction of the substrates;

the parallel direction moving unit that moves the substrate mounting part in a direction parallel to the surface of each substrate;

the gas supply unit having a plurality of processing gas supply parts in the stacking direction of the substrates, being the gas supply unit that supplies the processing gas into the processing chamber for applying processing to the surface of the substrate;

the exhaust unit that exhausts the atmosphere in the processing chamber; and

the controller that controls the vertical direction moving unit, the parallel direction moving unit and the gas supply unit,

the controller controlling the vertical direction moving unit so that the substrate mounting part, on which the substrates are mounted, is moved in the stacking direction of the substrates, when the processing gas is supplied into the processing chamber from the processing gas supply parts and processing is applied to the surface of the substrate, and controlling the parallel direction moving unit so that the substrate mounting part, on which the substrates are mounted, is moved in a direction parallel to the surface of the substrate.

In the aforementioned substrate processing apparatus, preferably, the gas supply unit has a plurality of gas supply nozzles for supplying the processing gas to a plurality of different places with equal intervals respectively in the processing chamber, and the controller controls the vertical direction moving unit so that the substrate mounting part, on which the substrates are mounted, is moved a distance of half between the respective processing gas supply parts in the stacking direction of the substrates.

Also, preferably the gas supply unit has a plurality of gas supply nozzles for supplying the processing gas to a plurality of different places with equal intervals respectively in the processing chamber, and the controller controls the vertical direction moving unit so that the substrate mounting part, on which the substrates are mounted, is moved a distance of half between the respective processing gas supply parts in a lower stream direction of the processing gas.

Also, preferably the controller controls the parallel moving unit so that the substrate mounting part, on which the substrates are mounted, in a direction parallel to the surface of the substrate, and desired processing is applied to the surface of the substrate, with the substrate mounting part fixed to a prescribed position asymmetrical to the center axis of the processing chamber. Further preferably, the prescribed position is a position near the inner wall of the processing chamber having the opening part of the exhaust unit in the processing chamber.

Also, preferably, the distance between the outer edge portion of the substrate mounting part and the inner wall of the processing chamber is set to be not less than the distance between stacked substrates.

Also, preferably, there is provided a rotating mechanism for rotating the substrate mounting part, and the controller controls the rotating mechanism so as to rotate the substrate mounting part, when the processing gas is supplied into the processing chamber form the processing gas supply parts and processing is applied to the surface of the substrate.

Also preferably, the controller controls the substrate mounting part so that the substrate mounting part is moved to the same position as the position for loading the substrate mounting part into the processing chamber and the substrate mounting part is unloaded from the processing chamber.

The controller moves the substrate mounting part according to the processing condition.

Another aspect of the present invention provides a substrate processing method, including:

loading the substrate for loading the substrate mounting part, on which a plurality of substrates are stacked and mounted, into the processing chamber;

supplying gas for applying processing to the surface of the substrate from at least two or more different positions in the stacking direction of the substrates;

moving vertically for moving the substrate mounting part in the stacking direction of the substrates in the processing chamber; and

unloading the substrate for unloading the substrate mounting part, on which the plurality of substrates are stacked, to the outside of the processing chamber.

Another aspect of the present invention provides the substrate processing method, including:

loading the substrate for loading the substrate mounting part, on which a plurality of substrates are stacked and mounted, into the processing chamber;

supplying gas for applying processing to the surface of the substrate from at least two or more different positions in the stacking direction of the substrates;

moving in parallel for moving the substrate mounting part in a direction parallel to the surface of the substrate in the processing chamber; and

unloading the substrate for unloading the substrate mounting part, on which the plurality of substrates are stacked, to the outside of the processing chamber.

In the above-described substrata processing method, preferably, there is also the step of moving the substrate mounting part vertically and laterally and making it rotate.

1. A substrate processing apparatus, comprising:
a processing chamber that stores a substrate mounting part on which a plurality of substrates are stacked and mounted;
a vertical direction moving unit that moves said substrate mounting part in a stacking direction of said substrates;
a gas supply unit having a plurality of processing gas supply parts in the stacking direction of said substrates, being the gas supply unit that supplies into said processing chamber processing gas for applying processing to a surface of each substrate;
an exhaust unit that exhausts an atmosphere in said processing chamber; and
a controller that controls said vertical direction moving unit and said gas supply unit,
said controller controlling said vertical direction moving unit so that said substrate mounting part, on which said substrates are stacked, is moved in the stacking direction of said substrates, in a condition that said processing gas is supplied into said processing chamber from said processing gas supply parts and processing is applied to the surface of said substrate.

2. A substrate processing apparatus, comprising:
a processing chamber that stores a substrate mounting part on which a plurality of substrates are stacked and mounted;
a parallel direction moving unit that moves said substrate mounting part in a direction parallel to the surface of each substrate;
a gas supply unit having a plurality of processing gas supply parts in a stacking direction of said substrates, being the gas supply unit that supplies processing gas into said processing chamber for applying processing to the surface of said substrate;
an exhaust unit that exhausts an atmosphere in said processing chamber; and
a controller that controls said parallel direction moving unit and said gas supply unit,
said controller controlling said parallel direction moving unit so that said substrate mounting part, on which said substrates are mounted, is moved in a direction parallel to the surface of each substrate, in a condition that said processing gas is supplied into said processing chamber from said processing gas supply parts and processing is applied to the surface of said substrate.

3. A substrate processing apparatus, comprising:
a processing chamber that stores a substrate mounting part on which a plurality of substrates are stacked and mounted;
a vertical direction moving unit that moves said substrate mounting part in a stacking direction of said substrates;
a parallel direction moving unit that moves said substrate mounting part in a direction parallel to the surface of each substrate;
a gas supply unit having a plurality of processing gas supply parts in the stacking direction of said substrates, being the gas supply unit that supplies processing gas into said processing chamber for applying processing to the surface of said substrate;
an exhaust unit that exhausts an atmosphere in said processing chamber; and
a controller that controls said vertical direction moving unit, said parallel direction moving unit and said gas supply unit,
said controller controlling said vertical direction moving unit so that said substrate mounting part, on which said substrates are mounted, is moved in the stacking direction of said substrates, in a condition that said processing gas is supplied into said processing chamber from said processing gas supply parts and processing is applied to the surface of said substrate, and controlling said parallel direction moving unit so that said substrate mounting part, on which said substrates are mounted, is moved in a direction parallel to the surface of said substrate.

4. The substrate processing apparatus according to claim 1, wherein said gas supply unit has a plurality of gas supply nozzles for supplying said processing gas to a plurality of different places with equal intervals respectively in said processing chamber, and said controller controls said vertical direction moving unit so that said substrate mounting part, on which said substrates are mounted, is moved a distance of half between the respective processing gas supply parts in the stacking direction of said substrates.

5. The substrate processing apparatus according to claim 1, wherein said gas supply unit has a plurality of gas supply nozzles for supplying said processing gas to a plurality of different places with equal intervals respectively in said processing chamber, and said controller controls said vertical direction moving unit so that said substrate mounting part, on which said substrates are mounted, is moved a distance of half between the respective processing gas supply parts in a lower stream direction of said processing gas.

6. The substrate processing apparatus according to claim 2, wherein the controller controls said parallel moving unit so that said substrate mounting part, on which said substrates are mounted, in a direction parallel to the surface of said substrate, and processing is applied to the surface of each substrate, with the substrate mounting part fixed to a prescribed position asymmetrical to a center axis of said processing chamber.

7. The substrate processing apparatus according to claim 6, wherein said prescribed position is a position near an inner wall of the processing chamber having an opening part of said exhaust unit in the processing chamber.

8. The substrate processing apparatus according to claim 2, wherein a distance between an outer edge portion of said substrate mounting part and an inner wall of said processing chamber is set to be not less than a distance between stacked substrates.

9. The substrate processing apparatus according to claim 3, wherein said gas supply unit has a plurality of gas supply nozzles for supplying said processing gas to a plurality of different places with equal intervals respectively in said processing chamber, and said controller controls said vertical direction moving unit so that said substrate mounting part, on which said substrates are stacked, is moved a distance of half between the respective processing gas supply parts in the stacking direction of said substrates.

10. The substrate processing apparatus according to claim 3, wherein said gas supply unit has a plurality of gas supply nozzles for supplying said processing gas to a plurality of different places with equal intervals respectively in said processing chamber, and said controller controls said vertical direction moving unit so that said substrate mounting part, on which said substrates are stacked, moves a distance of half between the respective processing gas supply parts in a lower direction of said processing gas.

11. The substrate processing apparatus according to claim 3, wherein said controller controls said parallel moving unit so that said substrate mounting part, on which said substrates are stacked, is moved in a direction parallel to the surface of each substrate, and processing is applied to the surface of said substrate, with the substrate mounting part fixed to a prescribed position which is asymmetrical to a center axis of said processing chamber.

12. The substrate processing apparatus according to claim 11, wherein said prescribed position is a position near an inner wall of the processing chamber having an opening part of said exhaust unit in the processing chamber.

13. The substrate processing apparatus according to claim 3, wherein a distance between an outer edge portion of said substrate mounting part and said inner wall of the processing chamber is not less than a distance between said stacked substrates.

14. The substrate processing apparatus according to claim 1, having a rotating mechanism for rotating said substrate mounting part, and said rotating mechanism is controlled so as to rotate said substrate mounting part, in a condition that said processing gas is supplied into said processing chamber from said processing gas supply parts and processing is applied to the surface of each substrate.

15. The substrate processing apparatus according to claim 1, wherein said controller controls said substrate mounting part so that said substrate mounting part is moved to the same position as the position for loading said substrate mounting part into said processing chamber and unloading said substrate mounting part from said processing chamber.

16. The substrate processing apparatus according to claim 1, wherein said controller moves said substrate mounting part according to a processing condition.

17. A substrate processing method, comprising the steps of:
loading a substrate for loading a substrate mounting part, on which a plurality of substrates are stacked and mounted, into a processing chamber;
supplying gas for applying processing to a surface of each substrate from at least two or more different positions in a stacking direction of said substrates;
moving vertically for moving said substrate mounting part in a stacking direction of said substrates in said processing chamber; and
unloading the substrate for unloading said substrate mounting part, on which said plurality of substrates are stacked and mounted, to outside of said processing chamber.

18. A substrate processing method, comprising:
loading a substrate for loading a substrate mounting part, on which a plurality of substrates are stacked and mounted, into a processing chamber;
supplying gas for applying processing gas to a surface of each substrate from at least two or more different positions in a stacking direction of said substrates;
moving in parallel for moving said substrate mounting part in a direction parallel to a surface of said substrate in said processing chamber; and
unloading the substrate for unloading said substrate mounting part, on which said plurality of substrates are stacked and mounted, to outside of said processing chamber.

19. The substrate processing method according to claim 17, comprising the steps of;
moving said substrate mounting part vertically and laterally and rotating this substrate mounting part.
